(19) United States
(12) Patent Application Publication
(10) Pub. No.: US 2026/0121614 A1
(43) Pub. Date: Apr. 30, 2026

(54) BULK ACOUSTIC WAVE DEVICE HAVING ISLAND REGION SURROUNDED BY ACTIVE REGION

(71) Applicant: Skyworks Global Pte. Ltd., Singapore (SG)

(72) Inventors: Martha Kennedy Small, Fort Collins, CO (US); Kwang Jae Shin, Yongin-si (KR); Stefan Bader, Fort Collins, CO (US)

(21) Appl. No.: 19/366,185

(22) Filed: Oct. 22, 2025

Related U.S. Application Data
(60) Provisional application No. 63/711,908, filed on Oct. 25, 2024.
(60) Provisional application No. 63/711,901, filed on Oct. 25, 2024.

(51) Int. Cl. H03H 9/17; H03H 9/02

(52) U.S. Cl. CPC H03H 9/173; H03H 9/02015; H03H 9/02086

(57) ABSTRACT

Aspects of this disclosure relate to a bulk acoustic wave that includes a piezoelectric layer with an island region laterally surrounded by an active region. The piezoelectric layer is less piezoelectric in the island region than in the active region. Related bulk acoustic wave dies, acoustic wave filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/711,908, filed October 25, 2024 and titled “BULK ACOUSTIC WAVE DEVICE HAVING ISLAND REGION SURROUNDED BY ACTIVE REGION,” and claims the benefit of priority of U.S. Provisional Application No. 63/711,901, filed October 25, 2024 and titled “BULK ACOUSTIC WAVE DEVICE HAVING PIEZOELECTRIC LAYER WITH ENGINEERED REGION SURROUNDED BY ACTIVE REGION,” the disclosure of each which are hereby incorporated by reference in their entireties and for all purposes.

### BACKGROUND

### TECHNICAL FIELD

The disclosed technology relates to acoustic wave devices. Embodiments of this disclosure relate to bulk acoustic wave device having a piezoelectric layer with an engineered region.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices. There is also a desire to implement BAW devices with efficient physical layouts.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave device having an island region and a main acoustically active region. The bulk acoustic wave device includes a first electrode, a second electrode, and a piezoelectric layer positioned between the first electrode and the second electrode. The piezoelectric layer has a lower magnitude effective piezoelectric coefficient in the island region of the bulk acoustic wave device than in the main acoustically active region of the bulk acoustic wave device. The main acoustically active region of bulk acoustic wave device laterally surrounds the island region of the bulk acoustic wave device.

The bulk acoustic wave device can have a rectangular shape in plan view. The rectangular shape can have rounded corners.

The bulk acoustic wave device can have a shape that includes two sides that are generally parallel in plan view. The shape can be selected from a group consisting of a trapezoid, a rhombus, a parallelogram, a hexagon, or an octagon.

The bulk acoustic wave device can include a raised frame structure in a frame region of the bulk acoustic wave device, The frame region can be around the main acoustically active region in plan view. The piezoelectric layer can have a lower magnitude effective piezoelectric coefficient in the frame region of the bulk acoustic wave device than in the main acoustically active region of the bulk acoustic wave device. The frame region can have a non-uniform width. The raised frame structure can include an oxide raised frame layer and a metal raised frame layer.

The bulk acoustic wave device can include a seed layer positioned between the first electrode and the piezoelectric layer in the island region. The bulk acoustic wave device can be free from the seed layer between the first electrode and the piezoelectric layer in the main acoustically active region. The island region can have a shape with non-parallel sides in plan view.

The bulk acoustic wave device can include a raised frame structure in the island region. The raised frame structure in the island region can include a plurality of raised frame layers.

The bulk acoustic wave device can include one or more additional island regions surrounded by the main acoustically active region in plan view. The piezoelectric layer can have a lower magnitude effective piezoelectric coefficient in each of the one or more additional island regions of the bulk acoustic wave device than in the main acoustically active region of the bulk acoustic wave device.

The magnitude of the effective piezoelectric coefficient of the piezoelectric layer in the island region can be less than 50% of the magnitude of the effective piezoelectric coefficient of the piezoelectric layer in the main acoustically active region. The magnitude of the effective piezoelectric coefficient of the piezoelectric layer in the island region can be less than 20% of the magnitude of the effective piezoelectric coefficient of the piezoelectric layer in the main acoustically active region.

The bulk acoustic wave device can include a cavity extending under the piezoelectric layer in the main acoustically active region and the island region.

Another aspect of this disclosure is a bulk acoustic wave device that includes a first electrode; a second electrode; a piezoelectric layer positioned between the first electrode and the second electrode, the piezoelectric layer having a first engineered region, an active region surrounding the first engineered region in plan view, and a second engineered region around the active region in plan view, the first engineered region and the second engineered region each having a lower magnitude effective piezoelectric coefficient than the active region; and a frame structure vertically overlapping with the second engineered region of the piezoelectric layer.

The first engineered region can have a shape configured to suppress a lateral mode

The bulk acoustic wave device can have a rectangular shape in plan view.

The piezoelectric can includes one or more additional engineered regions surrounded by the active region in plan view.

The second engineered region can have a non-uniform width around the active region to provide apodization.

The bulk acoustic wave device can include a second frame structure overlapping with the first engineered region. The second frame structure can include a plurality of raised frame layers. The second frame region structure can include a metal raised frame layer and an oxide raised frame layer.

The frame structure can include a metal raised frame layer and an oxide raised frame layer. The frame structure can include a recessed frame structure.

The bulk acoustic wave device can include a seed layer positioned between the piezoelectric layer and the first engineered region of the piezoelectric layer. The bulk acoustic wave device can be free from the seed layer between the active region of the piezoelectric layer and the first electrode.

The magnitude of the effective piezoelectric coefficient of the second engineered region of the piezoelectric layer can be less than 50% of the magnitude of the effective piezoelectric coefficient of the active region of the piezoelectric layer. The magnitude of the effective piezoelectric coefficient of the second engineered region of the piezoelectric layer can be less than 20% of the magnitude of the effective piezoelectric coefficient of the active region of the piezoelectric layer.

The bulk acoustic wave device can include a cavity extending under the active region of the piezoelectric layer, the first engineered region of the piezoelectric layer, and at least part of the second engineered region of the piezoelectric layer.

Another aspect of this disclosure is a bulk acoustic wave die that includes a bulk acoustic wave device in accordance with any suitable principles and advantages disclosed herein and a plurality of additional acoustic wave devices.

One or more of the additional bulk acoustic wave devices can have a rectangular shape in plan view. One or more of the additional bulk acoustic wave devices can a shape with two generally parallel sides in plan view.

Another aspect of this disclosure is an acoustic wave filter for filtering a radio frequency signal. The acoustic wave filter includes a bulk acoustic wave device in accordance with any suitable principles and advantages disclosed herein and a plurality of additional acoustic wave resonators. The bulk acoustic wave device and the plurality of additional acoustic wave resonators are configured to filter the radio frequency signal.

Another aspect of this disclosure is a multiplexer for filtering radio frequency signals. The multiplexer includes a first filter including a bulk acoustic wave device in accordance with any suitable principles and advantages disclosed herein, and a second filter coupled to the first filter at a common node.

Another aspect of this disclosure is a radio frequency module that includes a filter including a bulk acoustic wave device in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave device in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave device in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave device in accordance with any suitable principles and advantages disclosed herein.

### BRIEF DESCRIPTION OF THE DRAWINGS

Embodiments of this disclosure will now be described, by way of non-limiting example, with reference to the accompanying drawings.

FIGS. 1A, 1B and 1C are schematic top plan views of example rectangular bulk acoustic wave (BAW) devices with an island region according to embodiments.

FIG. 2 is a schematic cross-sectional diagram of a BAW device with an island region according to an embodiment.

FIG. 3A is a schematic cross-sectional diagram of a BAW device with a raised frame layer in an island region according to an embodiment.

FIG. 3B is a schematic cross-sectional diagram of a BAW device with a multi-layer raised frame structure in an island region according to an embodiment.

FIGS. 4A, 4B, 4C, and 4D are schematic top plan views of example rectangular BAW devices with an island region according to embodiments. The BAW devices of FIGS. 4C and 4D include frame regions that provide apodization.

FIGS. 5A and 5B are schematic top plan views of example rectangular BAW devices with a plurality of island regions according to embodiments.

FIG. 6 is a schematic diagram of a BAW die with rectangular BAW devices according to an embodiment.

FIGS. 7A and 7B are schematic top plan views of example BAW devices with at least one island region according to embodiments.

FIG. 8 is a schematic block diagram of an oscillator that includes a BAW device according to an embodiment.

FIG. 9 is a schematic block diagram of a sensor that includes a BAW device according to an embodiment.

FIG. 10A is a schematic diagram of a ladder filter that includes one or more BAW resonators according to an embodiment. FIG. 10B is schematic diagram of a band pass filter.

FIGS. 11A, 11B, 11C and 11D are schematic diagrams of multiplexers that include a filter with one or more BAW resonators according to an embodiment.

FIGS. 12, 13 and 14 are schematic block diagrams of modules that include a filter with one or more BAW resonators according to an embodiment.

FIG. 15 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

In certain bulk acoustic wave (BAW) resonators, parallel sides of an active region can cause relatively large spurs in the BAW resonator response as waves propagate back and forth between the parallel sides. In a lateral spurious mode, a standing wave can be generated by parallel sides of such BAW resonators. BAW resonators can have an apodization shape with non-parallel sides. Irregular or apodization shaped BAW devices can suppress a lateral spurious mode. The apodized physical layout can be less efficient in terms of area than using rectangular shaped BAW resonators arranged in a grid geometry. For example, a physical layout of a BAW die that includes BAW resonators with apodization shapes can have open space between BAW resonators.

A BAW device with a relatively high a quality factor (Q) is generally desirable. Increasing the Q of a given BAW device can effectively reduce energy losses. Such energy losses can include, for example, insertion losses within a filter or phase noise in an oscillator. BAW device performance can be enhanced and/or optimized by one or more of area, geometry, frame structure, or the like. Q can be boosted with a frame structure.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of layer that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. The main acoustically active region can be a region of a BAW device that generates a main resonant frequency. The main acoustically active region can be free from frame structures. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A raised frame structure can reduce lateral energy leakage from a main acoustically active region of a BAW device. The raised frame structure can create a resonance at a frequency that is below a resonant frequency of the main acoustically active region of the BAW device. This resonance can be below a main resonant frequency of the BAW device. A resonance associated with the raised frame structure can be referred to as a frame mode, and more specifically a raised frame mode. The raised frame mode can be undesirable in certain applications.

This disclosure provides technical solutions that can suppress and/or eliminate frame modes in BAW devices and that can also achieve efficient physical layouts. Such technical solutions can achieve relatively high Q. BAW devices disclosed herein include an engineered region of a piezoelectric layer in an island region with little or no acoustic activity. The shape of the island region can provide apodization in a rectangular shaped BAW device. The shape of the island region can provide apodization in BAW device having any suitable shape that includes two generally parallel sides, such as but not limited to a rectangle, a square, a trapezoid, a rhombus, a parallelogram, a hexagon, an octagon, or the like. BAW devices disclosed herein can also include another engineered region of a piezoelectric layer that can suppress a frame mode of a frame structure. These BAW devices can be referred to as having an engineered passive frame. In addition to having efficient physical layout, BAW devices disclosed herein can achieve significant performance improvements over other BAW devices. Filters that include BAW devices disclosed herein can provide improved performance in a variety of applications.

Aspects of this disclosure relate to a BAW device that includes an island region surrounded by an active region. The island region can be in a central part of the BAW device. The BAW device can also include a frame region around the active region. In the island region, there can be little or no acoustic activity. The island region can have an irregular and/or apodization shape. Sides of the island region can be non-parallel to outer sides of the active region and/or sides the frame region. The island region can provide apodization to reduce or eliminate a lateral spurious mode. The BAW device can have a rectangular shape in top plan view. The BAW device can have any other suitable shape in plan view that includes two generally parallel sides, such as but not limited to a trapezoid, a rhombus, a parallelogram, a hexagon, an octagon, or the like. An engineered region of a piezoelectric layer can be included the island region, where the engineered region is less piezoelectric than a region of the piezoelectric layer that laterally surrounds the engineered region. In certain embodiments, a frame structure can be positioned in the island region of the BAW device. In some applications, the BAW device can include one or more additional island regions laterally surrounded by the active region.

BAW devices with an island region can have a rectangular shape in top plan view and also suppress a lateral spurious mode. Such devices can be arranged in a grid and efficiently utilize area of a BAW die. The island region having little or no acoustic activity can contribute to one or more of desirable thermal dissipation, desirable ruggedness, or desirable power handling. Island regions disclosed herein can provide an in-device metal-insulator-metal (MIM) capacitor, where an engineered region of the piezoelectric layer is an insulator between electrodes of the BAW device. Such a MIM capacitor can be in parallel with the BAW device.

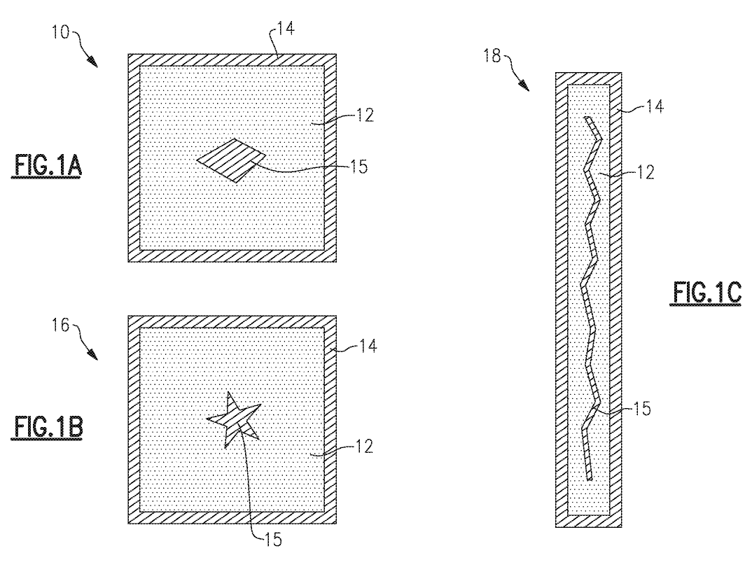

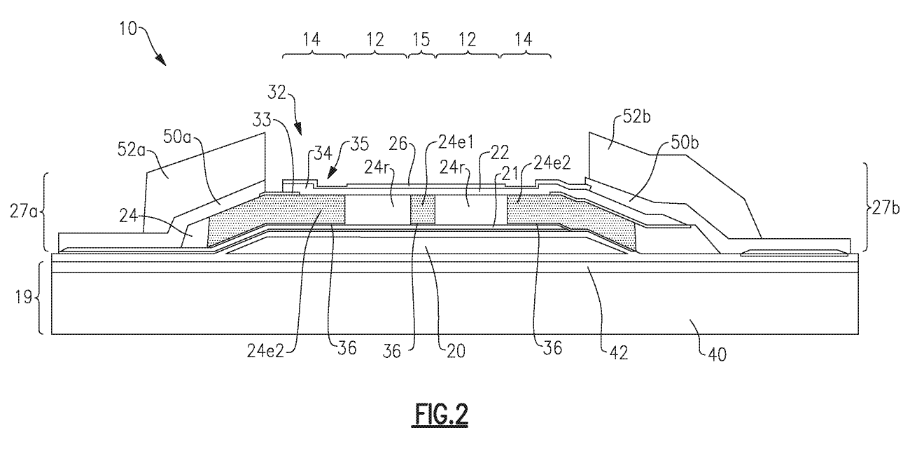

FIG. 1A is schematic top plan view of an example BAW device 10 with an island region 15 according to an embodiment. The BAW device 10 has a rectangular shape in plan view. Although not illustrated in FIG. 1A, the rectangular shape can have rounded corners in certain applications. As illustrated in FIG. 1A, the BAW device 10 includes the island region 15, an active region 12 surrounding the island region 15, and a frame region 14 around the active region 12. The frame region 14 can surround the active region 12 in plan view. The BAW device 10 can generate a bulk acoustic wave in the active region 12 having a resonant frequency.

The island region 15 can have little or no acoustic activity. The island region 15 can have an electromechanical coupling coefficient (kt²) that is close to zero. The BAW device 10 can include an engineered region of a piezoelectric layer positioned between electrodes of the BAW device 10 in the island region 15.

The island region 15 can have an irregular and/or apodization shape in top plan view. Sides of the island region 15 are non-parallel with a perimeter of the active region 12. Sides of the island region 15 are non-parallel with sides of the frame region 14 in the BAW device 10. Sides of the island region 15 are non-parallel with outer sides of the active region 12. This can suppress and/or prevent a standing wave between outer sides of the rectangular active region 12 and the island region 15. Accordingly, the island region 15 can provide apodization for the rectangular BAW device 10. Example shapes of the island region with sides that are non-parallel with outer sides of an active region and/or with sides of a frame region include, for example, the island region 15 shown in a FIG. 1A, the island region 15 shown in FIG. 1B, the island region 15 shown in FIG. 15C, a circular shaped island region in plan view, an oval shaped island region in plan view, etc.

The island region 15 can be relatively small compared to the total area of the BAW device 10. In certain applications, the island region 15 or a plurality of island regions 15 can consume in a range from 1% to 20% of the area of the BAW device 10. According to some of these applications, the island region(s) 15 can consume from 1% to 10% of the total area of the BAW device 10. With larger area of the island region(s) 15, a larger MIM capacitor can be in parallel with the BAW device 10. Accordingly, in applications where larger MIM capacitor capacitance is desired, a larger area of island region(s) 15 can be implemented. Similarly, in applications where little or no MIM capacitor capacitance is desired, a smaller area of island region(s) 15 can be implemented. A smaller area of the island region(s) 15 can result in a smaller total area of the BAW device 10 for the same active area.

The BAW device 10 includes a frame structure in the frame region 14. The frame structure can include a raised frame structure that can suppress a transverse mode of the BAW device 10. The BAW device 10 can have little or no acoustic activity in the frame region 14. The BAW device 10 can include an engineered region of a piezoelectric layer positioned between electrodes of the BAW device 10 that can suppress a frame mode associate with the frame region 14. Such a BAW device 10 can be referred to as having an engineered passive frame.

FIG. 1B is schematic top plan view of an example BAW device 16 with an island region 15 according to an embodiment. The BAW device 16 is like the BAW device 10 of FIG. 1A, except that the island region 15 has a different shape in these BAW devices. In the BAW device 16, the island region 15 has sides that are non-parallel with both the outer sides of the active region 12 and the sides of the frame region 14. The island region 15 has a star shape in plan view in the BAW device 16. Although certain island regions 15 shown in the drawings have corners, such as the star shaped island region 15 shown in FIG. 1B, any suitable shape having non-parallel sides can be implemented. For example, a circular shaped or oval shaped island region in plan view can be implemented in accordance with any suitable principles and advantages disclosed herein.

FIG. 1C is schematic top plan view of an example BAW device 18 with an island region 15 according to an embodiment. The BAW device 18 is like the BAW device 10 of FIG. 1A and the BAW device 16 of FIG. 1B, except that the island region 15 has a different shape in the BAW device 18. In the BAW device 18, the island region 15 has sides that are non-parallel with both the outer sides of the active region 12 and the sides of the frame region 14. In certain applications, the shape of the BAW device 18 having a higher aspect ratio between length and width compared to the BAW devices 10 and 16 may result in a higher Q.

FIG. 2 is a cross-sectional side view of the BAW device 10 of FIG. 1A according to an embodiment. Any suitable principles and advantages of the cross-section view of the BAW device 10 can apply to the BAW device 16 of FIG. 1B, the BAW device 18 of FIGS. 1 C, and/or any other suitable BAW device disclosed herein. As illustrated in FIG. 2, the BAW device 10 can include a support structure 19, an acoustic reflector (e.g., a cavity 20), a first electrode 21, a second electrode 22, a piezoelectric layer 24, a passivation layer 26, interconnect structures 27a and 27b, and a frame structure 32.

The piezoelectric layer 24 includes a regular region 24r and engineered regions 24e1 and 24e2. A region of the piezoelectric layer 24 that is not engineered can be referred to as a regular region 24r of the piezoelectric layer 24. The regular region 24r of the piezoelectric layer 24 is in the active region 12 of the BAW device 10. In the regular region 24r of the piezoelectric layer 24, the piezoelectric layer 24 is acoustically active. The first electrode 21, the second electrode 22, and the regular region 24r of the piezoelectric layer 24 overlap over the acoustic reflector (e.g., the cavity 20) and generate a bulk acoustic wave in the piezoelectric layer 24 in the active region 12 of the BAW device 10. The active region 12 generates a main bulk acoustic wave having a main resonant frequency of the BAW device 10 of FIG. 2 . Accordingly, the active region 12 can be referred to as the main acoustically active region of the BAW device 10 of FIG. 2.

A first engineered region 24e1 of the piezoelectric layer 24 is in the island region 15 of the BAW device 10. A second engineered region 24e2 of the piezoelectric layer 24 is in the frame region 14 of the BAW device 10. The frame structure 32 is also positioned in the frame region 14 and vertically overlaps the second engineered region 24e2 of the piezoelectric layer 24.

The first engineered region 24e1 of the piezoelectric layer 24 can be in a central area of the BAW device 10. Due to a low magnitude piezoelectric coefficient, the piezoelectric layer 24 can be acoustically inactive in the first engineered region 24e1. Accordingly, the BAW resonator 10 can be acoustically inactive and not resonating in the island region 15.

The varied distances between the island region 15 and the frame region 14 in the BAW device 10 can provide apodization for the active region 12 in the BAW device 10 that has a rectangular shape. This can provide lateral spurious mode suppression in a rectangular shaped BAW device 10. Rectangular shaped BAW devices can be physically laid out in less area compared to apodization shaped BAW devices with a similar active area. Accordingly, less die area can be used for a filter of rectangular shaped BAW resonators than similar apodization shaped BAW resonators.

In the BAW device 10, the frame structure 32 includes a raised frame structure including a first raised frame layer 33 and a second raised frame layer 34. The frame structure 32 also includes a recessed frame structure 35. In some other applications, a recessed frame structure can overlap with the regular region 24r of the piezoelectric layer 24. In such an application, the recessed frame structure is still in a frame region.

The frame structure 32 can be configured to suppress a transverse mode of the BAW device 10. The frame structure 32 can reduce or impede propagation of the transverse mode. As illustrated in FIG. 2, the frame structure 32 includes a multi-layer raised frame structure that includes a first raised layer 33 and a second raised frame layer 34. In certain embodiments, the first raised frame structure layer 33 is an oxide raised frame layer and the second raised frame layer 34 is a metal raised frame layer. The first raised frame layer 33 can include a low acoustic impedance material that has a lower acoustic impedance than the first electrode 21, the second electrode 22, and/or the piezoelectric layer 24. For example, the first raised frame layer 33 can include a silicon dioxide (SiO₂) layer, a silicon nitride (SiN) layer, a silicon carbide (SiC) layer, or any other suitable low acoustic impedance layer. The first raised frame layer 33 can be a dielectric layer. The first raised frame layer 33 can be an oxide layer. The second raised frame layer 34 can include a material that has a relatively high mass density. For instance, the second raised frame layer 34 can include molybdenum (Mo), tungsten (W), ruthenium (Ru), the like, or any suitable alloy thereof. In some embodiments, the second raised frame layer 34 and the second electrode 22 can be formed of the same material. The second raised frame layer 34 can be a metal layer. Alternatively, the second raised frame layer 34 can be a suitable non-metal material with a relatively high density. The density of the second raised frame layer 34 can be similar to or heavier than the density of the first electrode 21 and/or the second electrode 22.

The frame structure 32 can include a recessed frame structure 35 positioned between the active region 12 and the second raised frame layer 34. The recessed frame structure 35 can be formed by reducing the thickness of passivation layer 26 in a selected region.

The piezoelectric layer 24 can include a suitable piezoelectric material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as, but not limited to, scandium (Sc), chromium (Cr), magnesium (Mg), sulfur (S), yttrium (Y), silicon (Si), germanium (Ge), oxygen (O), hafnium (Hf), zirconium (Zr), titanium (Ti), tantalum (Ta), boron (B), niobium (Nb), or the like. In certain applications, the piezoelectric layer 24 can be AlN based layer doped with Sc. According to some of these applications, the piezoelectric layer 24 of the BAW device 10 can be an AlN based piezoelectric layer doped with 10% to 20% Sc. Doping the piezoelectric layer 24 can adjust the resonant frequency. Doping the piezoelectric layer 24 can increase the kt² of the BAW device 10. Doping to increase the kt² can be advantageous at higher frequencies where kt² can be degraded. In certain applications, a BAW device that includes two or more piezoelectric layers can be implemented with any suitable principles and advantages disclosed herein.

The engineered regions 24e1 and 24e2 of the piezoelectric layer 24 can each have a lower magnitude effective piezoelectric coefficient than the regular region 24r of the piezoelectric layer 24. For example, the engineered regions 24e1 and 24e2 of the piezoelectric layer 24 can have an effective piezoelectric coefficient with a magnitude that is less than 50%, less than 20%, or less than 10% of the magnitude of the effective piezoelectric coefficient of the regular region 24r of the piezoelectric layer 24. Even though the engineered regions 24e1 and 24e2 may have little or no piezoelectricity, the engineered regions 24e1 and 24e2 can be considered parts of the piezoelectric layer 24 of BAW devices of this disclosure.

The effective piezoelectric coefficient of the first engineered region 24e1 can be an aggregate piezoelectric coefficient for the entire first engineered region 24e1. The aggregate magnitude of the piezoelectric polarization vectors in the first engineered region 24e1 should be less than the magnitude in the regular region 24r. The lower magnitude effective piezoelectric coefficient can be a result of the non-aligned nature of piezoelectric material crystal orientations within the first engineered region 24e1 causing a lower aggregate magnitude of the piezoelectric polarization vectors.

The effective piezoelectric coefficient of the second engineered region 24e2 can be an aggregate piezoelectric coefficient for the entire second engineered region 24e2. The aggregate magnitude of the piezoelectric polarization vectors in the second engineered region 24e2 should be less than the magnitude in the regular region 24r. The lower magnitude effective piezoelectric coefficient can be a result of the non-aligned nature of piezoelectric material crystal orientations within the second engineered region 24e2 causing a lower aggregate magnitude of the piezoelectric polarization vectors.

The effective piezoelectric coefficient can be an effective piezoelectric coupling coefficient (e₃₃), for example. The first engineered region 24e2 of the piezoelectric layer 24 can suppress acoustic activity in the island region 15 of the BAW device 10. The second engineered region 24e2 of the piezoelectric layer 24 can suppress the frame mode associated with the raised frame layers 33, 34. BAW devices with an engineered region of a piezoelectric layer and a frame structure (e.g., the frame structure 32) disclosed herein can enable frame mode suppression and transverse mode suppression.

The engineered regions 24e1 and 24e2 can be formed in any suitable manner. For example, a seed layer 36 can be positioned over portions of the first electrode 21 where the engineered regions 24e1 and 24e2 area to be formed. The seed layer 36 can cause the piezoelectric layer 24 to be engineered in the engineered regions 24e1 and 24e2. The seed layer 36 can be a material that has poor crystallinity or is crystalline with a poor lattice match to the piezoelectric film applied over the seed layer 36. The piezoelectric layer 24 in the engineered regions 24e1 and 24e2 over the seed layer 36 can have relatively poor bulk piezoelectric properties compared to the piezoelectric layer 24 in the regular region 24r. The BAW device 10 is free from the seed layer 36 between the first electrode 21 and the regular region 24r of the piezoelectric layer 24. The seed layer 36 can be directly over the first electrode 21. The seed layer 36 can be a layer formed by atomic layer deposition, for example. The seed layer 36 can include, but is not limited to, an oxide, a nitride, a carbide, a carbon structure (e.g., graphene or diamond), a boride, or any suitable combination thereof. In certain applications, the seed layer 36 can include one or more of aluminum oxide, silicon, silicon carbide, aluminum nitride such as doped aluminum nitride or undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer 36 can have a thickness that is in a single digit nanometer range. In some embodiments, the seed layer 36 can have a thickness that is in a range from 10 nanometers to 100 nanometers.

In some embodiments, a uniform piezoelectric material can be deposited and then the engineered regions 24e1 and 24e2 of the piezoelectric material can be modified to be less piezoelectric than the regular region 24r. For example, ions can be implanted to modify the structure and properties of the piezoelectric material by ion implantation to form the engineered regions 24e1 and 24e2. In such embodiments, the piezoelectric material can be engineered from a side opposite the first electrode 21. In such embodiments, the seed layer 36 can be omitted from the BAW device 10.

A boundary or border between the regular region 24r and the engineered region 24e2 of the piezoelectric layer 24 can be the boundary or border between the active region 12 and the frame region 14. The border between the regular region 24r and the engineered region 24e2 can be adjusted toward the central region of a BAW device or away from the central region of a BAW device relative to the BAW device 10 shown in FIG. 2

The first electrode 21 can be referred to as a lower electrode. The first electrode 21 can have a relatively high acoustic impedance. The first electrode 21 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 21 in certain applications. The second electrode 22 can be referred to as an upper electrode. The thickness of the first electrode 21 can be approximately the same as the thickness of the second electrode 22 in the active region 12 of the BAW device 10.

The passivation layer 26 can be a silicon dioxide layer. The passivation layer 26 can be any other suitable passivation layer, such as aluminum oxide, silicon carbide, aluminum nitride, silicon nitride, silicon oxynitride, or the like. The passivation layer 26 can include a dielectric material.

The support structure 19 can include a support substrate 40 and an intermediate layer 42 between the support substrate 40 and the first electrode 21. The support substrate 40 can be a semiconductor substrate. For example, the support substate 40 can be a silicon substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or one or more other suitable functional layers. In some embodiments, the intermediate layer 42 can be completely or partially omitted. In some such embodiments, a portion of the first electrode 21 can directly contact the support substrate 40. The intermediate layer 42 can be relatively thin. For example, the intermediate layer 42 is typically significantly thinner than the support substrate 40. Heat generated by the BAW device 10 can dissipate through the first electrode 21 to the support substrate 40 at a location where there is no cavity 20 between the first electrode 21 and the support substrate 40.

As shown in FIG. 2, a first interconnect structure 27a can include one or more conductive layers such as a first conductive layer 50a and a second conductive layer 52a. Similarly, a second interconnect structure 27b can include one or more conductive layers such as a first conductive layer 50b and a second conductive layer 52b. The first conductive layers 50a, 50b and the second conductive layers 52a, 52b can each include a material suitable for interconnecting the BAW device 10 and one or more other component (e.g., another resonator) in a filter, an external component, or a ground connection. The first conductive layers 50a, 50b and/or the second conductive layers 52a, 52b can be highly conductive. For example, the first conductive layers 50a, 50b and/or the second conductive layers 52a, 52b can be more electrically conductive than the first electrode 21 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 20 (e.g., an air cavity) can be formed between the support substrate 40 and the first electrode 21. The cavity 20 is an example of an acoustic reflector. The BAW device 10 be a film bulk acoustic wave resonator (FBAR). In some other embodiments, there can be a solid acoustic mirror in place of the cavity 20 and such a BAW device can be a BAW solidly mounted resonator (SMR).

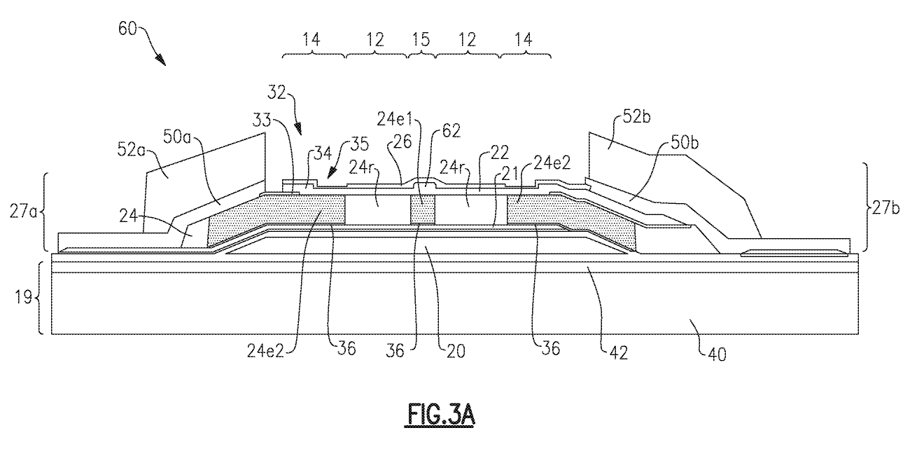

In certain applications, a second frame structure can be included in an island region of a BAW device. The second frame structure can provide additional mass loading to suppress any remnant piezoelectric effect in the island region. Any suitable second frame structure can be implemented in an island region in accordance with any suitable principles and advantage disclosed herein. FIGS. 3A and 3B illustrate example cross sectional views of BAW devices with a second frame structure in an island region.

FIG. 3A is a schematic cross-sectional a BAW device 60 with a raised frame layer 62 in an island region 15 according to an embodiment. The BAW device 60 is like the BAW device 10 of FIG. 2, except that the BAW device 60 also includes the raised frame layer 62 in the island region 15. The raised frame layer 62 can provide additional mass loading in the island region 15 compared to the active region 12. The raised frame layer 62 can include a same material as the electrode 22 in some applications. The raised frame layer 62 can be a metal layer.

FIG. 3B is a schematic cross-sectional a BAW device 65 with a multi-layer raised frame structure in an island region 15 according to an embodiment. The BAW device 65 is like the BAW device 60 of FIG. 3A, except that the BAW device 65 also includes a second raised frame layer 67 in the island region 15. The raised frame layers 62 and 67 can provide additional mass loading in the island region 15 compared to the active region 12. The second raised frame layer 67 can include a same material as the raised frame layer 33 and/or the passivation layer 26 in some applications. The second raised frame layer 67 can be an oxide layer. For instance, the second raised frame layer 67 can be a silicon dioxide layer.

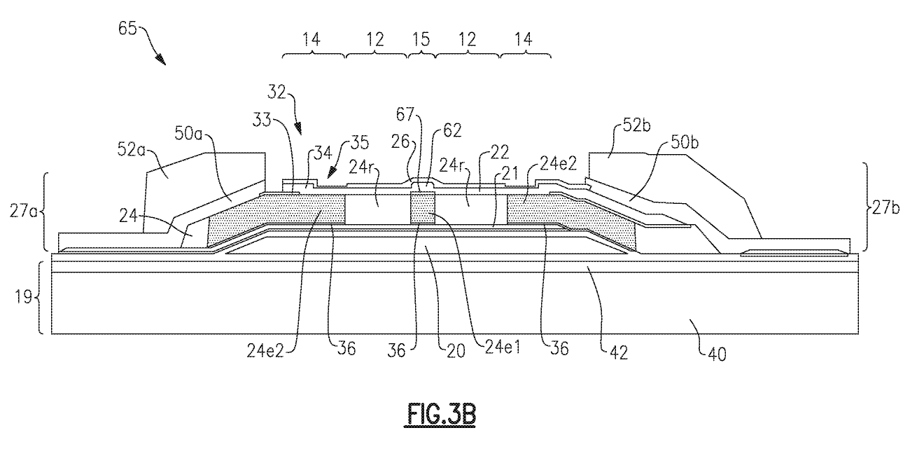

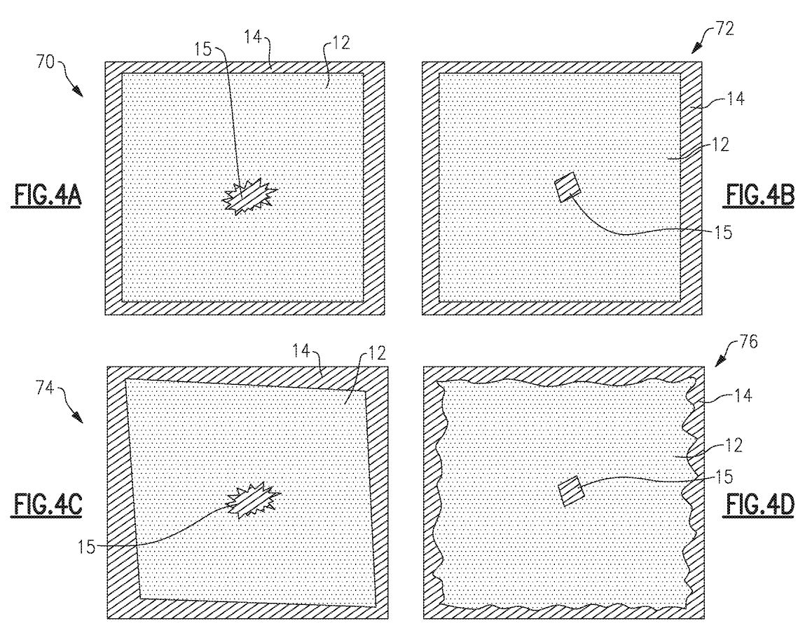

Rectangular BAW devices and other BAW devices that include two generally parallel sides can have a variety of island regions to create apodization. Such BAW devices can include an engineered region of a piezoelectric layer. In certain instances, such BAW devices can include a raised frame structure in the island region. Additional example BAW devices are shown in FIGS. 4A an 4B. These example BAW devices can be implemented in accordance with any suitable principles and advantages disclosed herein.

FIG. 4A is a schematic top plan view of a BAW device 70 that includes an island region 15 according to an embodiment. In the BAW device 70, apodization can be provided by shape of the island region 15 relative to outer sides of the active region 12 and the frame region 14.

FIG. 4B is a schematic top plan view of a BAW device 72 that includes an island region 15 according to an embodiment. In the BAW device 72, apodization can be provided by shape of the island region 15 relative to outer sides of the active region 12 and the frame region 14.

Certain BAW devices can include a raised frame structure that vertically overlaps with an engineered region of a piezoelectric layer, where the raised frame structure includes an oxide raised frame layer and a metal raised frame layer. Simulations indicate that widths of the oxide raised frame layer and the metal raised frame layer in such a BAW device can be varied without significantly impacting Q. Accordingly, frame width can be varied to create apodization in rectangular shaped BAW devices and desirable Q can be achieved. Example BAW devices with rectangular shapes that include an island region and frame regions with non-uniform widths will be discussed with reference to FIGS. 4C and 4D. Any suitable principles and advantages of these BAW devices can be implemented together with each other and/or any other suitable principles and advantages disclosed herein.

FIG. 4C is a schematic top plan view of example rectangular BAW device 74 with an island region 15 and a frame region 14 with a non-uniform width according to an embodiment. In the BAW device 74, a frame region 14 having a varied width is included around the active region 12. Apodization can be provided by (i) the shape of the active region 12 and (ii) the island region 15.

FIG. 4D is a schematic top plan view of example rectangular BAW device 76 with an island region 15 and a frame region 14 with a non-uniform width according to an embodiment. In the rectangular BAW device 76, both the island region 15 and the shape of the frame region 14 can provide apodization. The shape of the frame region 14 also impacts the shape of the active region 12 in the BAW device 76. As shown in FIG. 4D, the frame region 14 can have an irregular shape. The frame region 14 in the BAW device 76 is illustrated as having sides facing the active region 12 that each include a plurality of curves. As also illustrated in FIG. 4D, the active region 12 has sides that correspond to the shape of the inner sides of the frame region 14. A frame region with non-uniform width can have any suitable shape in accordance with any suitable principles and advantages disclosed herein.

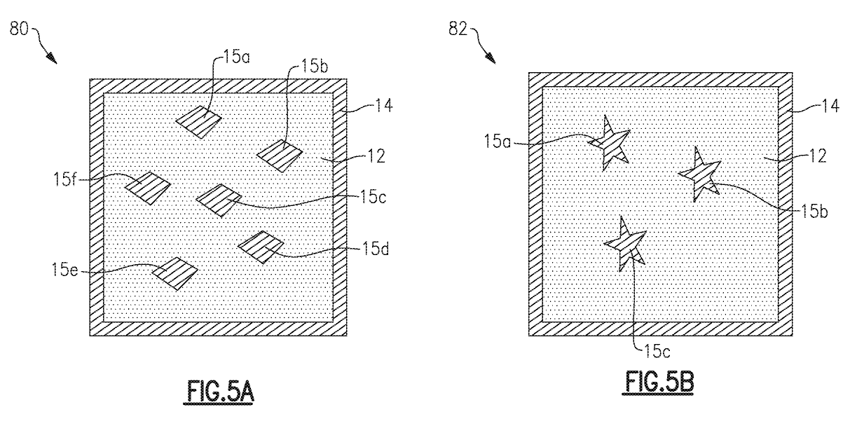

In certain applications, more than one island region can be included in a BAW device. A plurality of island regions in a rectangular BAW device may provide desired apodization in certain applications. Such island regions can have any suitable shape in accordance with any suitable principles and advantages disclosed herein. In certain applications, a BAW device can include two or more island regions with a same shape in accordance with any suitable principles and advantages disclosed herein. In some applications, a BAW device can include two or more island regions with different shapes in accordance with any suitable principles and advantages disclosed herein. A BAW device can include a plurality of island regions and a frame region with non-uniform width that also provides apodization. Example rectangular BAW devices with the plurality of island regions will be discussed with reference to FIGS. 5A and 5B.

FIG. 5A is a schematic top plan view of an example rectangular BAW device 80 with a plurality of island regions 15a, 15b, 15c, 15d, 15e, and 15f according to an embodiment. The BAW device 80 is like the BAW device 10 of FIG. 1A, except that more island regions are included in the BAW device 80. While the BAW device 80 includes 6 island regions 15a to 15f, a BAW device can include any suitable number of island regions in accordance with any suitable principles and advantages disclosed herein.

FIG. 5B is a schematic top plan view of an example rectangular BAW device 82 with a plurality of island regions 15a, 15b, and 15c according to an embodiment. The BAW device 82 is like the BAW device 16 of FIG. 1B, except that more island regions are included in the BAW device 82. The BAW device 82 is like the BAW device 80 of FIG. 5A, except that the BAW device 80 includes a different number of island regions and island regions have a different shape.

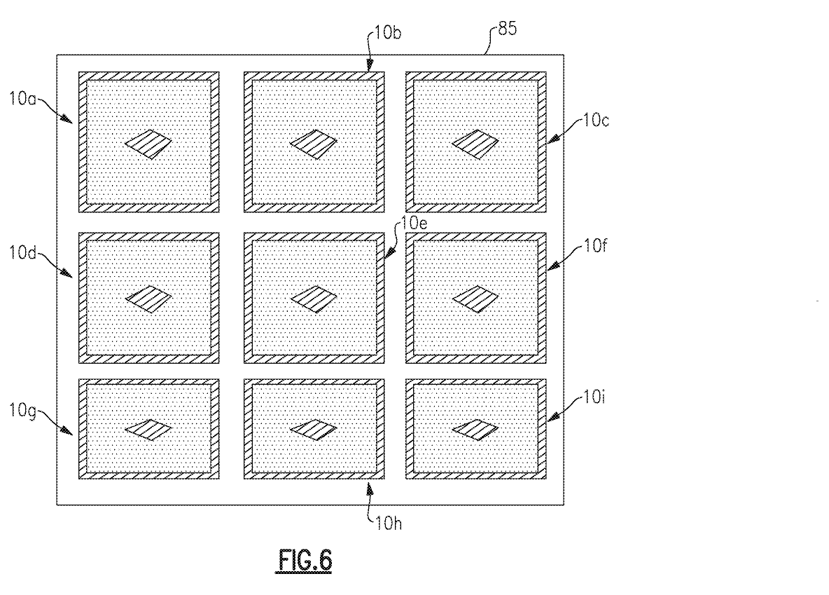

FIG. 6 is a schematic diagram of a BAW die 85 with rectangular BAW devices 10a to 10iaccording to an embodiment. The rectangular BAW devices 10a to 10ieach include an island region laterally surrounded by an active region in accordance with any suitable principles and advantages disclosed herein. On the BAW die 85, the rectangular BAW devices 10a to 10i are arranged in a grid and efficiently use the area of the BAW die 85. The rectangular BAW devices 10a to 10ican be implemented using less physical die area than similar BAW devices with apodization shapes and acoustically active regions with the same area.

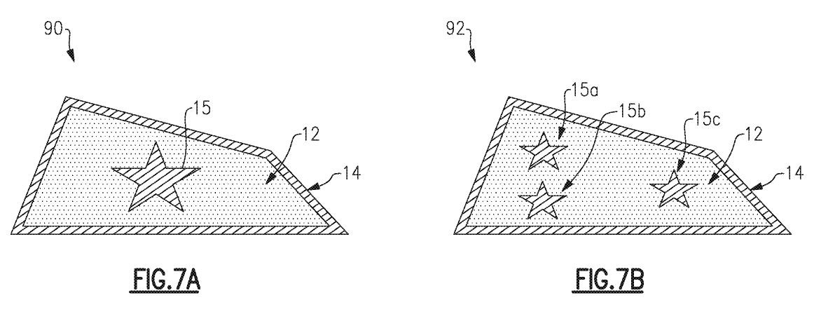

Island regions can be implemented in a variety of BAW resonators. Such BAW resonators can have any suitable shape in top plan view. In certain applications, including one or more island regions can provide apodization together with the resonator shape. In such applications, apodization of the BAW resonator shape can be reduced while still achieving desirable lateral mode suppression. Such BAW resonators may not necessarily have a rectangular shape in top plan view. In some applications, a BAW resonator can have a shape in plan view that includes two generally parallel sides, such as but not limited to a trapezoid, a rhombus, a parallelogram, a hexagon, an octagon, or the like. Such BAW resonators can be implemented with any suitable principles and advantages disclosed herein. Example BAW devices having an apodization shape and one or more island regions will be discussed with reference to FIGS. 7A and 7B. These BAW devices can be implemented with any other suitable principles and advantages disclosed herein.

FIG. 7A is a schematic top plan views of example BAW device 90 with an island region 15 according to an embodiment. The BAW device 90 can have resonator shape with non-parallel sides. This resonator shape of the BAW device 90 can provide apodization. The island region 15 can also contribute to apodization. With the island region 15, the resonator shape can be more rectangular and still provide desirable lateral mode suppression.

FIG. 7B is a schematic top plan views of example BAW device 92 with a plurality of island regions 15a, 15b, and 15c according to an embodiment. The BAW device 92 is like to BAW device 90 of FIG. 7A, except that a plurality of island regions 15a, 15b, and 15c are included in the BAW device 92. Including more than one island region can increase lateral mode suppression in certain applications.

Although embodiments disclosed herein may be discussed with reference to piezoelectric layers with engineered regions, any suitable principles and advantages disclosed herein can be applied to BAW devices that include less acoustically active material between a pair of electrodes in some or all of a frame region compared to material between the pair of electrodes in a main acoustically active region. Such less acoustically active material can include a dielectric material having a relatively low piezoelectric coupling coefficient. In some applications, such less acoustically active material can be a layer of different material than the piezoelectric layer that is between the pair of electrodes in the main acoustically active region of the BAW device.

The BAW devices disclosed herein can be implemented in various applications. BAW devices disclosed herein can be implemented in a variety of applications. Applications of these BAW devices include, but are not limited to, a BAW resonator for a filter that filters an electrical signal, an oscillator such as an oscillator for a clock generator, a sensor (e.g., a gas sensor, a particle sensor, a mass sensor, a pressure or touch sensor, etc.), a delay line such as a delay line for radar and/or instrumentation applications, an actuator, a microphone, and a speaker. Filters that include BAW devices can be implemented in a variety of applications including, but not limited to, mobile phones, base stations, repeaters, relays, wireless communication infrastructure, access points, customer premises equipment (CPE), and distributed antenna systems. Oscillators that include a BAW resonator can replace crystal oscillators in a variety of applications, such as but not limited to electronic timing products. In some applications, an oscillator that includes a BAW resonator and a crystal oscillator can both be implemented. Example applications will now be discussed.

FIG. 8 illustrates that an oscillator 140 can include a BAW resonator 132 according to an embodiment. The oscillator 140 can be any oscillator that could benefit from a BAW wave resonator. For example, the oscillator 140 can be included in a radio frequency front end. The oscillator 140 can be implemented in place of another oscillator, such as a quartz oscillator, in a variety of applications. The oscillator 140 can provide a frequency reference. The oscillator 140 can generate a local oscillator signal for up converting and/or a down converting a signal.

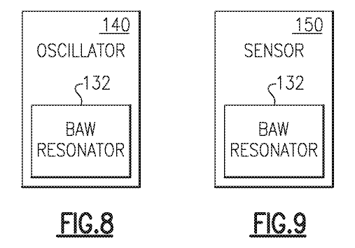

FIG. 9 illustrates that a sensor 150 can include a BAW resonator 132 according to an embodiment. The sensor 150 can be any sensor that could benefit from a BAW resonator. For example, the sensor 150 can be arranged to sense pressure, to sense temperature, or to sense any other suitable parameter. In some instances, the sensor 150 can be configured for liquid sensing applications.

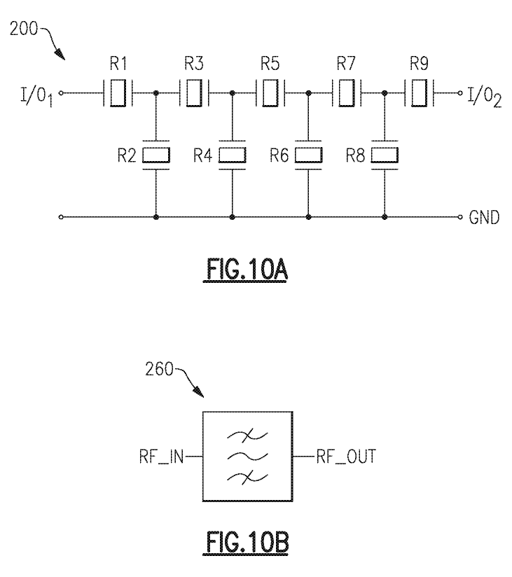

BAW devices disclosed herein can be implemented in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, BAW resonators disclosed herein can be implemented in filters with one or more other types of resonators and/or with passive impedance elements, such as one or more inductors and/or one or more capacitors. An example filter topology will be discussed with reference to FIG. 10A. In certain applications, a subset or one or more BAW resonators of a filter can include one or more island regions in accordance with any suitable principles and advantages disclosed herein. According to some other applications, all BAW resonators of a filter can include at least one island region in accordance with any suitable principles and advantages disclosed herein.

FIG. 10A is a schematic diagram of a ladder filter 200 that includes a BAW resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein in certain instances.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio – Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band, a Global Positioning System (GPS) operating band, a Bluetooth operating band, a ZigBee operating band, a WiMax operating band, etc.

The BAW resonators disclosed herein can be advantageous for implementing BAW resonators with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications. The BAW resonators disclosed herein can be implemented with an efficient physical layout.

FIG. 10B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

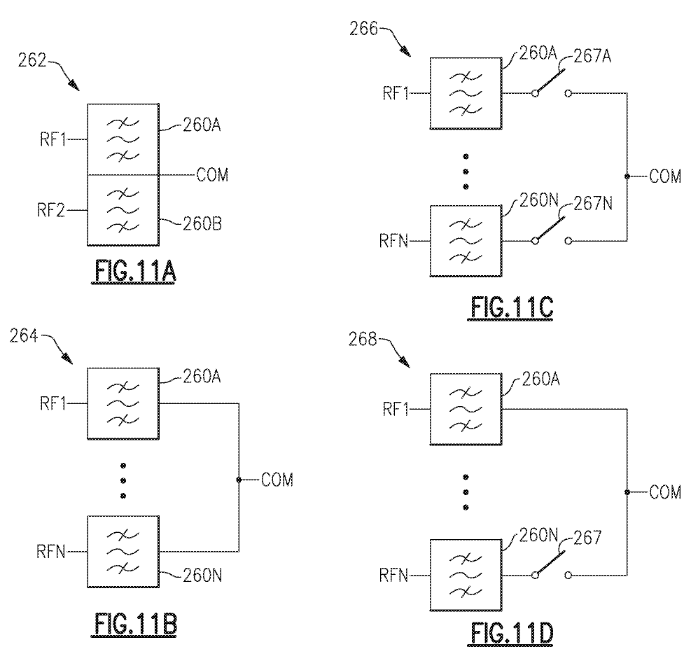

The BAW devices disclosed herein can be implemented in a standalone filter and/or in a filter of any suitable multiplexer. Such filters can be any suitable topology, such as a ladder filter topology. The filter can be a band pass filter arranged to filter a radio frequency signal in a 4G LTE band and/or 5G NR band. The filter can be a band pass filter having a passband corresponding to an operating band of any other suitable wireless communication standard, such as WiFi, etc. Example multiplexers will be discussed with reference to FIGS. 11A to 11D. Any suitable principles and advantages of these multiplexers can be implemented together with each other.

FIG. 11A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 11B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 11C is a schematic diagram of a multiplexer 266 that includes an acoustic wave filter according to an embodiment. The multiplexer 266 is like the multiplexer 264 of FIG. 11B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 11D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

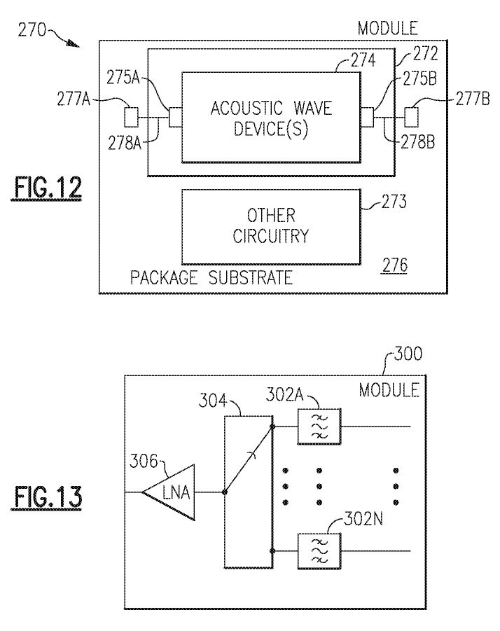

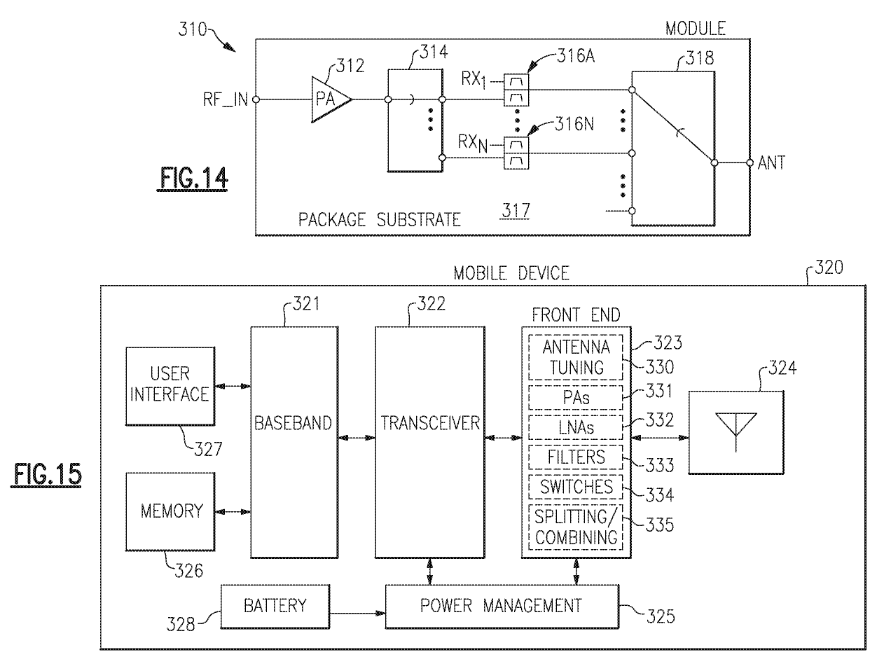

Acoustic wave devices disclosed herein can be implemented in a variety of packaged modules. Some example packaged modules will now be disclosed in which any suitable principles and advantages of the BAW resonators disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 12, 14, and 14 are schematic block diagrams of illustrative packaged modules according to certain embodiments. Any suitable combination of features of these packaged modules can be implemented with each other.

FIG. 12 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW resonators in certain applications.

The acoustic wave component 272 shown in FIG. 12 includes one or more acoustic wave devices 274 and terminals 275A and 275B. The one or more acoustic wave devices 274 include one or more BAW resonators implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 6. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 13 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 14 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 8 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW resonator in accordance with any suitable principles and advantages disclosed herein. Similarly, one or more of the receive filters can include a BAW resonator in accordance with any suitable principles and advantages disclosed herein. Although FIG. 8 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

The BAW resonators disclosed herein can be implemented in wireless communication devices. FIG. 15 is a schematic block diagram of a wireless communication device 320 that includes a BAW resonator according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 15 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW resonators in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 15, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 15, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 6 GHz, or in a frequency range from about 2 GHz to 10 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave device having an island region and a main acoustically active region, the bulk acoustic wave device comprising:
a first electrode;
a second electrode; and
a piezoelectric layer positioned between the first electrode and the second electrode, the piezoelectric layer having a lower magnitude effective piezoelectric coefficient in the island region of the bulk acoustic wave device than in the main acoustically active region of the bulk acoustic wave device, and the main acoustically active region of bulk acoustic wave device laterally surrounds the island region of the bulk acoustic wave device.

2. The bulk acoustic wave device of claim 1 wherein the bulk acoustic wave device has a rectangular shape in plan view.

3. The bulk acoustic wave device of claim 2 wherein the rectangular shape has rounded corners.

4. The bulk acoustic wave device of claim 1 wherein the bulk acoustic wave device has a shape that includes two sides that are generally parallel in plan view.

5. The bulk acoustic wave device of claim 1 wherein the island region has a shape with non-parallel sides in plan view.

6. The bulk acoustic wave device of claim 1 further comprising a raised frame structure in a frame region of the bulk acoustic wave device, the frame region being around the main acoustically active region in plan view.

7. The bulk acoustic wave device of claim 6 wherein the piezoelectric layer has a lower magnitude effective piezoelectric coefficient in the frame region of the bulk acoustic wave device than in the main acoustically active region of the bulk acoustic wave device.

8. The bulk acoustic wave device of claim 7 wherein the frame region has a non-uniform width.

9. The bulk acoustic wave device of claim 6 wherein the raised frame structure includes an oxide raised frame layer and a metal raised frame layer.

10. The bulk acoustic wave device of claim 1 further comprising a seed layer positioned between the first electrode and the piezoelectric layer in the island region, the bulk acoustic wave device being free from the seed layer between the first electrode and the piezoelectric layer in the main acoustically active region.

11. The bulk acoustic wave device of claim 1 further comprising a raised frame structure in the island region.

12. The bulk acoustic wave device of claim 11 wherein the raised frame structure in the island region includes a plurality of raised frame layers.

13. The bulk acoustic wave device of claim 1 further comprising one or more additional island regions surrounded by the main acoustically active region in plan view, the piezoelectric layer having a lower magnitude effective piezoelectric coefficient in each of the one or more additional island regions of the bulk acoustic wave device than in the main acoustically active region of the bulk acoustic wave device.

14. The bulk acoustic wave device of claim 1 wherein the magnitude of the effective piezoelectric coefficient of the piezoelectric layer in the island region is less than 50% of the magnitude of the effective piezoelectric coefficient of the piezoelectric layer in the main acoustically active region.

15. The bulk acoustic wave device of claim 1 wherein the magnitude of the effective piezoelectric coefficient of the piezoelectric layer in the island region is less than 20% of the magnitude of the effective piezoelectric coefficient of the piezoelectric layer in the main acoustically active region.

16. The bulk acoustic wave device of claim 1 further comprising a cavity extending under the piezoelectric layer in the main acoustically active region and the island region.

17. A bulk acoustic wave die comprising:
a bulk acoustic wave device having an island region and a main acoustically active region, the bulk acoustic wave device including a first electrode, a second electrode, and a piezoelectric layer positioned between the first electrode and the second electrode, the piezoelectric layer having a lower magnitude effective piezoelectric coefficient in the island region of the bulk acoustic wave device than in the main acoustically active region of the bulk acoustic wave device, and the main acoustically active region of bulk acoustic wave device laterally surrounds the island region of the bulk acoustic wave device; and
a plurality of additional bulk acoustic wave devices.

18. The bulk acoustic wave die of claim 17 wherein one or more of the plurality of additional bulk acoustic wave devices has a rectangular shape in plan view.

19. The bulk acoustic wave die of claim 17 wherein one or more of the plurality of additional bulk acoustic wave devices has a shape that includes two generally parallel sides in plan view.

20. A wireless communication device comprising:
a radio frequency front end including a filter that includes a bulk acoustic wave device having an island region and a main acoustically active region, the bulk acoustic wave device including a first electrode, a second electrode, and a piezoelectric layer positioned between the first electrode and the second electrode, the piezoelectric layer having a lower magnitude effective piezoelectric coefficient in the island region of the bulk acoustic wave device than in the main acoustically active region of the bulk acoustic wave device, and the main acoustically active region of bulk acoustic wave device laterally surrounds the island region of the bulk acoustic wave device;
an antenna coupled to the radio frequency front end;
a transceiver in communication with the radio frequency front end; and
a baseband system in communication with the transceiver.
